(19) United States
(12) Patent Application Publication
(10) Pub. No.: US 2025/0143052 A1
(43) Pub. Date: May 1, 2025

(54) METHOD FOR FORMING RESONANT CAVITY LIGHT EMITTING ELEMENTS AND OPTICAL DEVICE USING THE SAME

(71) Applicant: MICLEDI MICRODISPLAYS BV, Leuven (BE)

(72) Inventors: Soeren STEUDEL, Herent (BE); Giuseppe BUSCEMI, Leuven (BE)

(21) Appl. No.: 18/691,401

(22) PCT Filed: Mar. 20, 2023
(86) PCT No.: PCT/EP2023/057025

§ 371 Date: Mar. 12, 2024

(51) Int. Cl. H10H 20/80; H10H 20/01; H10H 20/833; H10H 20/857

(52) U.S. Cl. CPC H10H 20/862; H10H 20/01335; H10H 20/018; H10H 20/0364; H10H 20/833; H10H 20/857

(57) ABSTRACT

A method (100) is provided for forming resonant cavity light emitting elements. The method comprises a step (101) of forming a first structure comprising a first substrate, a stop layer, a light emitting epitaxial structure, a conductive oxide layer, and second a substrate dielectrically bonded to the conductive oxide layer. The method further comprises a step (102) of etching from the first substrate up to the stop layer. Additionally, the method comprises a step (103) of forming a plurality of light emitting mesa modules, each having a metal layer deposited on the stop layer. Furthermore, the method comprises a step (104) of hybrid bonding the first structure to a carrier substrate to form a second structure. Furthermore, the method comprises a step (105) of etching from the second substrate up to the conductive oxide layer. Moreover, the method comprises a step (106) of depositing a distributed Bragg reflector on top of the conductive oxide layer, thereby forming the resonant cavity light emitting elements.

The invention relates to cavity length h definition in complementary metal-oxide-semiconductor (CMOS) processing and integration of resonant cavity light emitting elements, e.g. resonant cavity light emitting diode (RCLED), with wafer-to-wafer (W2W) hybrid bonding backplane, especially for micro-LED displays.

Generally, RCLEDs comprise a structure where the active region is sandwiched between two reflective mirrors with a cavity length of one wavelength or a wavelength multiple of the emitting light. The resulting resonance amplifies the spontaneous emission perpendicular to the surface. These characteristics increase the overall system efficiency, especially for augmented reality (AR) and similar applications, compared to conventional LEDs. For Example, the document U.S. Pat. No. 7,825,006 B2 presents a process to fabricate RCLEDs on SIC substrate by implementing a Group-III nitride epitaxial semiconductor structure with two reflective mirrors.

However, the definition of the cavity length is a crucial parameter to tune, especially to define RCLED performances, because it maximizes the integrated intensity. Furthermore, Group-III nitride based RCLEDs require complex fine-tuning for cavity length definition. Moreover, conventional RCLED manufacturing process and backplane integration require separate CMOS fabrication process.

Accordingly, an object of the invention is to provide a method for forming resonant cavity light emitting elements and an optical device that can address the aforementioned limitations, especially to perform cavity length definition prior and during processing in a full CMOS environment.

The object is solved by the features of the first independent claim for the method, and by the features of the second independent claim for the optical device. The dependent claims contain further developments.

According to a first aspect of the invention, a method is provided for forming resonant cavity light emitting elements. The method comprises a step of forming a first structure comprising a first substrate, a stop layer or an etch stop layer or an etch and processing stop layer, a light emitting epitaxial structure, a conductive oxide layer, and a second substrate dielectrically bonded to the conductive oxide layer. The method further comprises a step of etching from the first substrate up to the stop layer.

Additionally, the method comprises a step of forming a plurality of light emitting mesa modules, each having a metal layer and/or a dielectric structure deposited on the stop layer. Furthermore, the method comprises a step of hybrid bonding the first structure to a carrier substrate to form a second structure. Furthermore, the method comprises a step of etching from the second substrate up to the conductive oxide layer. Moreover, the method comprises a step of depositing a distributed Bragg reflector on top of the conductive oxide layer, thereby forming the resonant cavity light emitting elements.

Therefore, the invention facilitates the manufacturing and integration of RCLEDs in a full CMOS environment with W2W hybrid bonding integration backplane, especially suitable for micro-LED displays. The invention further provides a scheme to effectively and accurately perform the cavity length definition prior and during processing, especially by introducing the stop layer in the epitaxial stack. In this regard, the stop layer effectively supports the etching process (e.g. as an etch stop layer and/or a processing stop layer) as well as defines one side of the cavity, where the other side being the conductive oxide layer surface and/or the distributed Bragg reflector interface.

Preferably, the shape of a cross-section of the light emitting mesa modules is a slope shape. Additionally or alternately, the light emitting mesa modules are formed in a parabolic or semi-parabolic shape. Furthermore, the method may comprise a step of passivating exposed areas or sidewalls along the light emitting mesa modules. In this regard, the passivating step comprises performing atomic layer deposition and/or ion implantation and/or bombarding with plasma. The application of a passivation layer advantageously protects the mesa sidewalls during subsequent processing steps and further prevents current leakage around the emission layer.

Preferably, a thickness of the stop layer, the light emitting epitaxial structure, and the conductive oxide layer, collectively, defines a cavity length for the resonant cavity emitting light elements, preferably corresponding to one wavelength of a light to be emitted by the resonant cavity light emitting elements. In other words, the stop layer, the light emitting epitaxial structure, and the conductive oxide layer collectively form a cavity structure, and the thickness of said cavity structure defines the cavity length, preferably corresponds to one wavelength of the light to be emitted.

Preferably, the formation of the first structure comprises a step of growing a buffer layer, the stop layer, the light emitting epitaxial structure, and the conductive oxide layer, successively, on the first substrate. The light emitting epitaxial structure comprises a first highly-doped layer, an emission layer, and a second highly-doped layer, successively. In this regard, the stop layer is provided between the buffer layer and the first highly-doped layer. The formation of the first structure further comprises a step of dielectric bonding to the second substrate at the conductive oxide layer to form the first structure.

Preferably, the buffer layer is an n-doped buffer layer, especially an n-type Gallium Nitride (nGaN) layer. The first highly-doped layer is an n-doped layer, especially an n-type Gallium Nitride (nGaN) layer. The second highly-doped layer is a p-doped layer, especially a p-type Gallium Nitride (pGaN) layer. The emission layer is a quantum well layer, especially an Indium Gallium Nitride (InGaN) and/or Gallium Nitride (GaN) based multiple quantum well (MQW) multi-layer. Therefore, the processing and fine-tuning of GaN-based RCLEDs, especially on a CMOS processing flow, are advantageously incorporated.

Preferably, the stop layer comprises or is an Indium Gallium Nitride (InGaN) and/or Aluminum Indium Gallium Nitride (AlInGaN) and/or Aluminum Gallium Nitride (AlGaN) layer. In other words, the stop layer comprises a material from the group InGaN, AlInGaN and AlGaN. Alternatively, the stop layer comprises or is a dielectric layer, preferably an oxide based dielectric layer (e.g. Silica, SiO₂).

Preferably, the formation of the second structure comprises the steps of flipping over the first structure, and hybrid bonding the first structure to the carrier substrate comprising a plurality of contact pads so as to bond the plurality of light emitting mesa modules with the respective contact pads. In this regard, the hybrid bonding refers to a bonding process that combines a dielectric bond with embedded metal to form interconnections.

Preferably, the conductive oxide layer is an optically transparent oxide layer, preferably comprises or is a transparent oxide based alloy (e.g. Indium Tin Oxide, ITO). Advantageously, the conductive oxide layer has the properties of adequate electrical conductivity and optical transparency, easy to be deposited as a thin film, and adequate chemical resistance to moisture.

Preferably, the metal layer comprises or is a Titanium layer and/or an Aluminum layer and/or bilayers thereof. More preferably, the metal layer comprises at least one Titanium layer and at least one Aluminum layer.

Alternatively, the metal layer comprises or is a plurality of conductive layers, preferably Titanium based oxide layers (e.g. Titanium Oxides, TiOx) and/or Hafnium based oxide layers (e.g. Hafnium Oxides, HfOx) and/or bilayers thereof. In other words, the metal layer may comprise or is a conductive distributed Bragg reflector.

Further alternatively, the metal layer comprises or is a plurality of dielectric layers and at least one metallic layer to form a hybrid optical reflector.

Preferably, the distributed Bragg reflector comprises or is a multi-layer oxide based reflector, preferably comprising Tantalum based oxide layers (e.g. Tantalum Pentoxide, Ta₂O₅) and/or Niobium based oxide layers (e.g. Niobium Pentoxide, Nb₂O₅) and/or Silicon based oxide layers (e.g. Silica, SiO₂) and/or bilayers thereof.

For instance, a Silica layer and a Tantalum/Niobium oxide layer may be repeatedly stacked under quarter-wavelength conditions (based on the desired wavelength of the light to be emitted), and the reflectance or transmittance of the desired wavelength band may be increased by adjusting the thicknesses of individual layers and the number of stacked layers.

Preferably, the etching corresponds to a dry etching process and/or a chemical-mechanical planarization process and/or a combination thereof. Advantageously, a very fast processing scheme is incorporated that is easy to start and stop, and less sensitive to temperature.

Preferably, the stop layer has a thickness less than 20 nm, preferably between 10 nm to 20 nm, more preferably between 10 nm to 15 nm.

According to a second aspect of the invention, an optical device is provided that comprises a plurality of resonant cavity light emitting elements. In this regard, each of the plurality of resonant cavity light emitting elements comprises a carrier substrate, a metal layer hybrid bonded with the carrier substrate, a stop layer on top of the metal layer, a first highly-doped layer on top of the stop layer, an emission layer on top of the first highly-doped layer, a second highly-doped layer on top of the emission layer, a conductive oxide layer on top of the second highly-doped layer, and a distributed Bragg reflector on top of the conductive oxide layer.

Preferably, the stop layer, the first highly-doped layer, the emission layer, the second highly-doped layer, and the conductive oxide layer are configured to define a cavity length for the resonant cavity light emitting elements, preferably corresponding to one wavelength of a light to be emitted by the resonant cavity light emitting elements.

It is to be noted that the optical device according to the second aspect corresponds to the method according to the first aspect and its implementation forms. Accordingly, the optical device of the second aspect achieves the same advantages and effects as the method of the first aspect and its respective implementation forms.

Exemplary embodiments of the invention are now further explained with respect to the drawings by way of example only, and not for limitation. In the drawings:

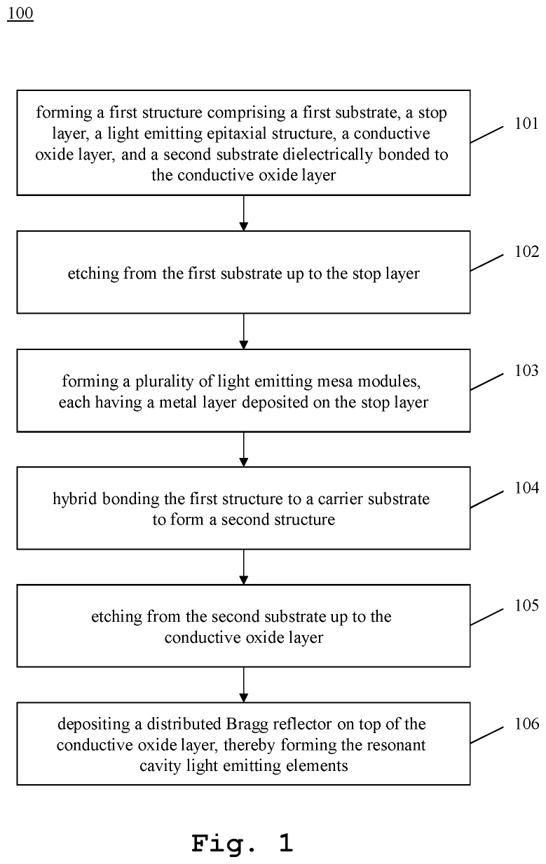

FIG. 1 shows an exemplary embodiment of the method according to the first aspect of the invention;

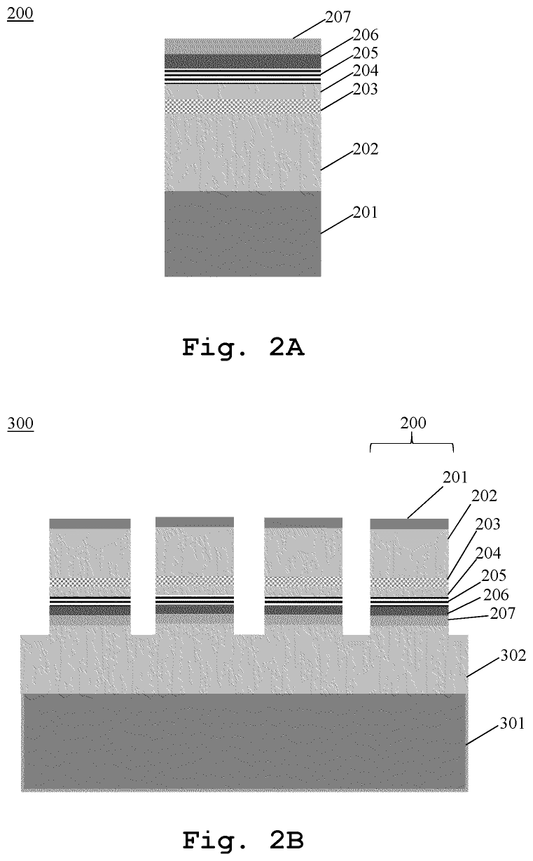

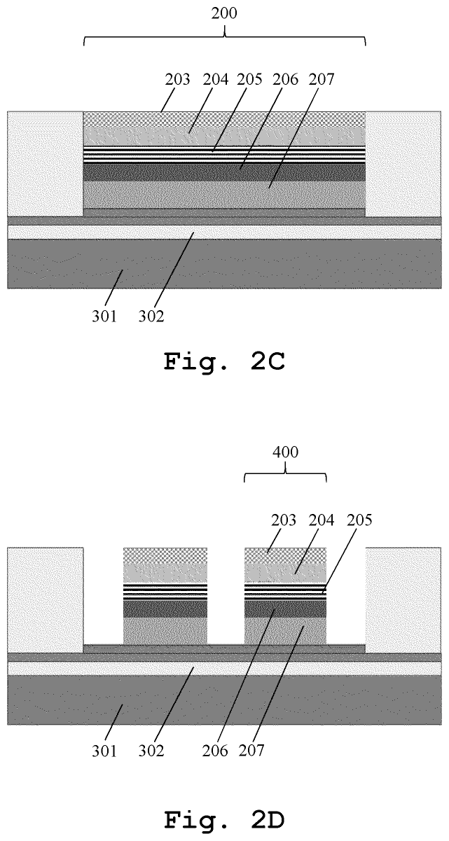

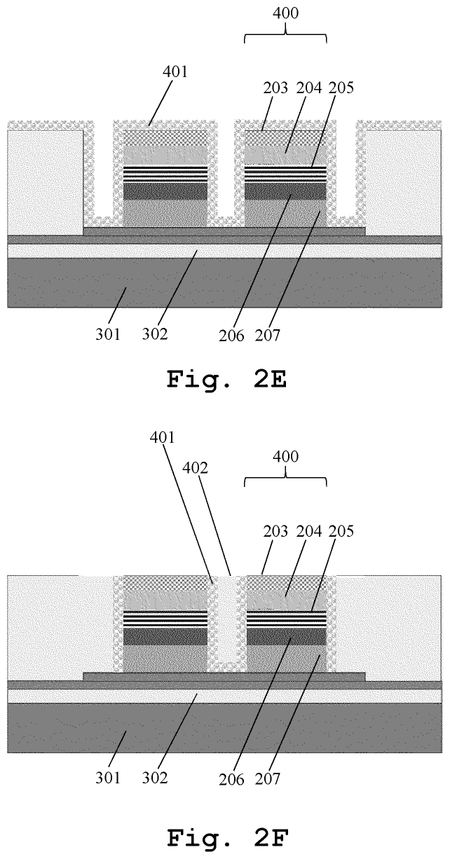

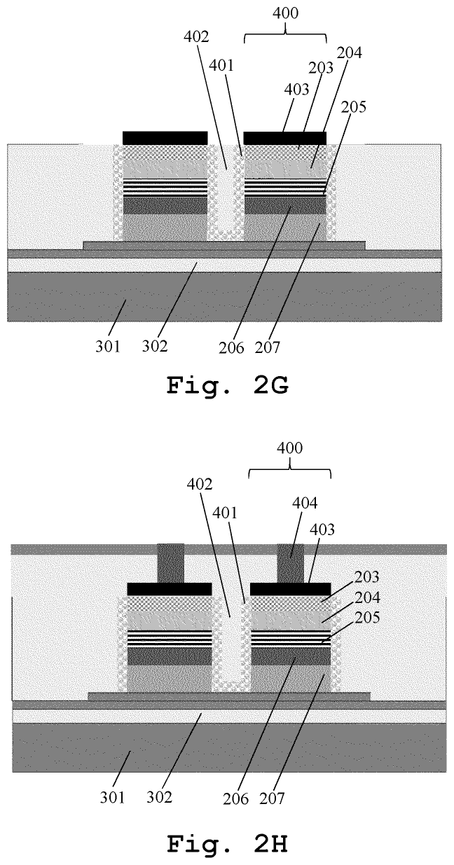

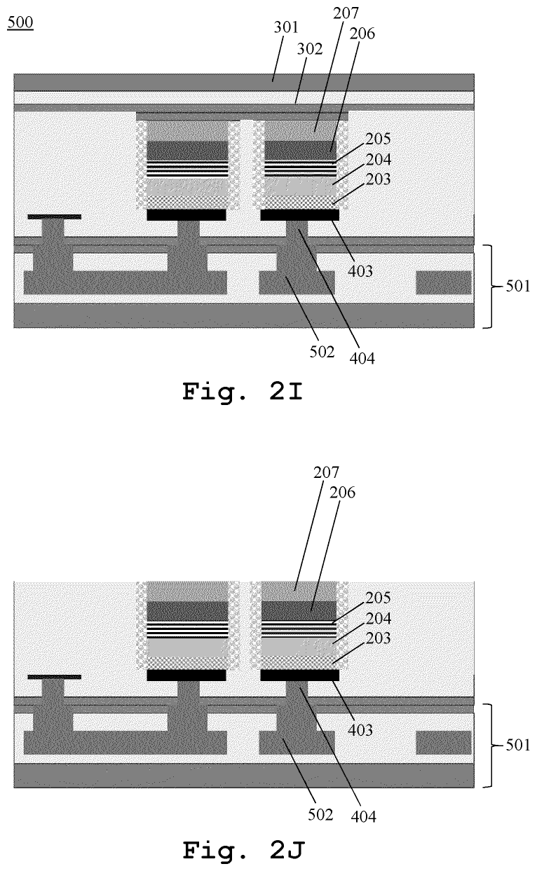

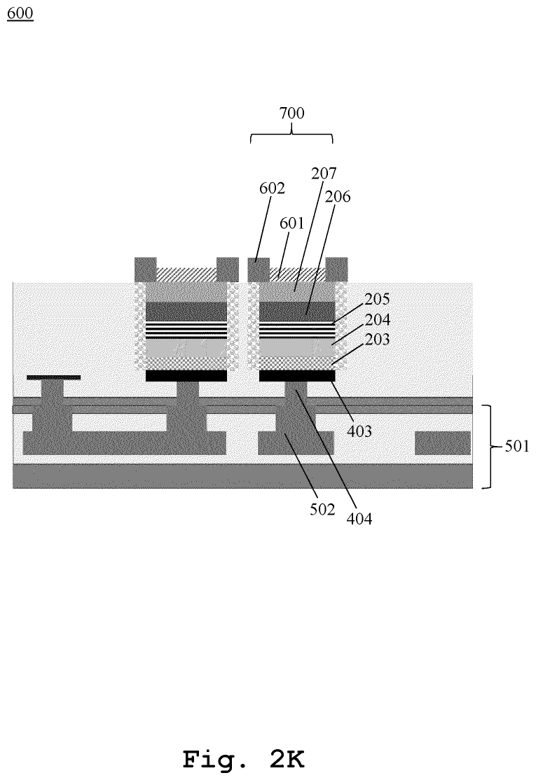

FIG. 2A shows a first process step of an exemplary embodiment of the fabrication process;

FIG. 2B shows a second process step of the exemplary embodiment of the fabrication process;

FIG. 2C shows a third process step of the exemplary embodiment of the fabrication process;

FIG. 2D shows a fourth process step of the exemplary embodiment of the fabrication process;

FIG. 2E shows a fifth process step of the exemplary embodiment of the fabrication process;

FIG. 2F shows a sixth process step of the exemplary embodiment of the fabrication process;

FIG. 2G shows a seventh process step of the exemplary embodiment of the fabrication process;

FIG. 2H shows an eighth process step of the exemplary embodiment of the fabrication process;

FIG. 2I shows a ninth process step of the exemplary embodiment of the fabrication process;

FIG. 2J shows a tenth process step of the exemplary embodiment of the fabrication process; and

FIG. 2K shows an eleventh process step of the exemplary embodiment of the fabrication process.

Reference will now be made in detail to the embodiments of the present invention, examples of which are illustrated in the accompanying drawings. However, the following embodiments of the present invention may be variously modified and the range of the present invention is not limited by the following embodiments. Reference signs for similar entities in different embodiments are partially omitted.

In FIG. 1, an exemplary embodiment of the method 100 according to the first aspect of the invention is illustrated. In a first step 101, a first structure is formed comprising a first substrate, a stop layer, a light emitting epitaxial structure, a conductive oxide layer, and a second substrate dielectrically bonded to the conductive oxide layer. In a second step 102, etching is performed from the first substrate up to the stop layer. In a third step 103, a plurality of light emitting mesa modules are formed, each having a metal layer deposited on the stop layer.

In a fourth step 104, the first structure is hybrid bonded to a carrier substrate to form a second structure. In a fifth step 105, etching is performed from the second substrate up to the conductive oxide layer. Finally, in a sixth step 106, a distributed Bragg reflector is deposited, especially for each light emitting mesa modules, on top of the conductive oxide layer, thereby forming the resonant cavity light emitting elements.

In FIGS. 2A-2K, an exemplary embodiment of the fabrication process is illustrated. Particularly, in FIG. 2A, a first process step of the fabrication process is illustrated. The first process step corresponds to the formation of an epitaxial stack 200, especially by growing epitaxial layers on a first substrate 201 (e.g. silicon substrate). The epitaxial growth process may be performed by growing a buffer layer 202 comprising n-type GaN, hereinafter referred to as N—GaN buffer layer, followed by a stop layer 203 comprising a material from the group InGaN, AlInGaN and AlGaN, having a thickness preferably between 10-20 nm.

The process further facilitates the growth of a light emitting epitaxial structure or LED epitaxial structure, especially comprising an n-type GaN layer 204, hereinafter referred to as N—GaN layer, an emission layer or active layer or MQWs 205, and a p-type GaN layer 206, hereinafter referred to as P—GaN layer. As such, the stop layer 203 is provided within the epitaxial stack 200, especially between the N—GaN buffer layer 202 and the N—GaN layer 204. Moreover, a conductive oxide layer 207, especially comprising Indium Tin Oxide and hereinafter referred to as ITO layer, is provided on top of the LED epitaxial structure, especially on top of the P—GaN layer 206.

In FIG. 2B, a second process step of the fabrication process is illustrated. Particularly, the second process step corresponds to the formation of a first structure 300 by flipping over and by means of dielectric bonding the epitaxial stack 200 with a second substrate 301 at the ITO layer 207. Hence, the first structure 300 comprises (from top to bottom direction as shown in FIG. 2B) the first substrate 201, the N—GaN buffer layer 202, the stop layer 203, the N—GaN layer 204, the emission layer 205, the P—GaN layer 206, the ITO layer 207, bonding dielectric or dielectric layer 302, and the second substrate 301. Preferably, the second substrate 301 is realized in a 300 mm silicon wafer, especially with a thickness of 775 nm.

This technique advantageously allows III-V integration on a CMOS fabrication. The process may be performed by realizing the epitaxial stack 200 on the incoming wafer, by depositing a bonding layer on the ITO layer 207, by dicing the wafer slighter larger than the LED optical area, by flipping and dielectric bonding to the 300 mm silicon wafer 301.

In FIG. 2C, a third process step of the fabrication process is illustrated. Particularly, the third process step corresponds to the planarization of the first structure 300. The process initiates the etching, especially dry etching, of the first structure 300 from the first substrate 201 side (i.e. from top to bottom direction of the first structure 300 as shown in FIG. 2B), up to the stop layer 203 to etch away or remove the first substrate 201 and the N—GaN buffer layer 202.

For instance, the third process step may initiate a step for etching the first substrate 201, followed by a step for dielectric deposition and planarization (e.g. chemical mechanical planarization, CMP) of the etched surface, followed by a step for etching the N—GaN buffer layer 202, followed by a step for dielectric deposition and planarization of the etched surface. The introduction of the stop layer 203 in the epitaxial stack 200 effectively allows the etching process and to stop the process, thereby defining one side of the cavity with a high accuracy.

In FIG. 2D, a fourth process step of the fabrication process is illustrated. Particularly, the fourth process step corresponds to the formation of mesa modules 400 on the first structure 300. The mesa modules 400 may be etched with a slope sidewall (e.g. by implementing a sloped mesa etch mask), and may comprise the stop layer 203, the N—GaN layer 204, the emission layer 205, the P—GaN layer 206, and the ITO layer 207.

The fourth process step may additionally perform passivation of the exposed areas or etched sidewalls of the mesa modules 400. In this regard, the passivation may comprise atomic layer deposition and/or ion implantation and/or bombarding with plasma. Alternatively, an oxide based passivation layer may be formed, such as a SiO₂ layer and/or a combination of dielectric to form a DBR, which may act as a reflector to reflect the emitted light.

In FIG. 2E, a fifth process step of the fabrication process is illustrated. Particularly, the fifth process step corresponds to the dielectric insulation of the mesa modules 400. For instance, during the fifth process step, the mesa modules 400 are laterally etched in a Tetramethyl Ammonium Hydroxide solution (TMAH etching) to perform lateral anisotropic etching.

Afterwards, insulation films (e.g. Aluminium Oxide, Al₂O₃) are deposited, e.g. by means of atomic layer deposition. Further, dielectric films (e.g. Silicon Nitride, SiNx) are deposited, e.g. by means of atomic layer deposition. Hence, the insulation layer 401 may comprise multiple layers of insulation films and dielectric films. This achieves a high degree of electrical and optical isolation between the neighboring mesa modules 400.

In FIG. 2F, a sixth process step of the fabrication process is illustrated. Particularly, the sixth process step corresponds to the planarization of the mesa modules 400. In this regard, oxide deposition may be carried out (e.g. the oxide filling 402 between and/or around the mesa modules 400 as shown) followed by a CMP process for each of the mesa modules 400. The CMP process is preferably stopped at the stop layer 203.

As such, the introduction of the stop layer 203 in the epitaxial stack 200 further acts as a process stop layer for the CMP process, which simplifies the fine-tuning of the cavity length during the process to accurately define one side of the cavity.

In FIG. 2G, a seventh process step of the fabrication process is illustrated. Particularly, the seventh process step corresponds to the metal layer 403 deposition on the mesa modules 400. In this regard, the metal layer 403 acts as a cavity mirror at one side of the cavity. For instance, the deposition of the metal layer 403 may include the deposition of an Aluminum layer or film or films followed by the deposition of a Titanium layer or film or films.

Alternatively, the metal layer 403 may be formed as a conductive distributed Bragg reflector. This can be achieved, e.g., by depositing multiple conductive layers or films (e.g. TiOx, HfOx) to form a reflector with stacked conductive layers.

In FIG. 2H, an eighth process step of the fabrication process is illustrated. Particularly, the eighth process step corresponds to the formation of n-side contacts or N-contacts 404 on the mesa modules 400. Preferably, the N-contacts 404 are copper (Cu) contacts that are formed by means of a Cu-damascene process, followed by dielectric deposition.

Generally, the damascene process is an additive process that makes use of the etching of dielectrics instead of etching the metal/copper. At first, the dielectric is deposited and etched according to a defined photoresist pattern, with an optional step of barrier layer deposition. Subsequently, copper is deposited, e.g. by chemical vapor deposition, CVD, or by physical vapor deposition, PVD, with reflow, or in electrochemical/galvanic processes. Afterwards, the copper is polished by CMP. The damascene process described herein corresponds to a single damascene process. However, a dual damascene process can also be implemented within this fabrication process.

In FIG. 2I, a ninth process step of the fabrication process is illustrated. Particularly, the ninth process step corresponds to the formation of a second structure 500 by flipping over the first structure 300 after forming the N-contacts 404, and by hybrid bonding with a carrier substrate 501.

The carrier substrate 501 corresponds to a Si-CMOS backplane that comprises a plurality of contact pads 502. The respective mesa modules 400, especially the N-contacts 404 of the respective mesa modules 400 are bonded with the respective contact pads 502 of the Si-CMOS backplane.

It is to be noted that hybrid bonding generally forms an attachment that combines two different kinds of bonds, especially a dielectric bond and a metal bond, where the latter is usually embedded in a dielectric bonding surface. In particular, the process conditions may be chosen as for conventionally known bonding techniques, i.e. temperature, pressure, and so on. Additionally, a post bond annealing may be applied in order to improve the overall bond shear strength.

In FIG. 2J, a tenth process step of the fabrication process is illustrated. Particularly, the tenth process step corresponds to the exposure of the ITO surface, i.e. the other side of the cavity.

The process step may include the etching or removal of the second substrate 301 followed by the etching or removal of the bonding dielectric or dielectric layer 302. The removal of the second substrate 301 and/or the dielectric layer 302 may comprise grinding and/or dry etching and/or wet etching and/or CMP.

In FIG. 2K, an eleventh process step of the fabrication process is illustrated. Particularly, the eleventh process step corresponds to the deposition of the diffractive Bragg distributor 601 and P-contacts 602 formation.

The process step may comprise the deposition of the diffractive Bragg distributor 601, preferably adding an oxide cap or an oxide beanie structure, followed by a Cu-damascene process to form the P-contacts 602. For instance, the deposition of the diffractive Bragg distributor 601 with the oxide cap may follow an etching of diaphragm, filling with Copper, and polishing the Copper (e.g. CMP) up to the oxide cap.

The distributed Bragg reflector 601 may be formed as a multi-layer reflector, with bilayers of Ta₂O₅ and SiO₂ or with bilayers of Nb₂O₅ and SiO₂. Said bilayers may be repeatedly stacked under λ/4 conditions (λ being the wavelength of the light to be emitted), and the reflectance or transmittance of the desired wavelength band may be increased by adjusting the thicknesses of individual layers and the number of stacked layers.

The process step may further comprise passivation with Aluminum metallization, e.g. N-side metallization, for facilitating front-side, e.g. P-side, interconnection.

As such, the resulting optical device 600 comprises the resonant cavity light emitting elements or RCLED modules 700, each comprising (from bottom to top as shown) the carrier substrate 501 including the contact pad 502, the metal layer 403 comprising the N-contact 403 hybrid bonded with the carrier substrate 501, the stop layer 203 on top of the metal layer 403, the N—GaN layer 204 on top of the stop layer 203, the emission layer 205 on top of the N—GaN layer 204, the P—GaN layer 206 on top of the emission layer 205, the ITO layer 207 on top of the P—GaN layer 206, the distributed Bragg reflector 601 on top of the ITO layer 207, and the P-contacts 602 conductively connected to the ITO layer 207.

In this regard, the cavity length for the RCLED module 700 is defined by the cavity structure, especially comprising the stop layer 203, the N—GaN layer 204, the emission layer 205, the P—GaN layer 206, and the ITO layer 207. In other words, the stop layer 203 defined one side, e.g. bottom side, of the cavity or cavity structure and the surface of the ITO layer 207 defines the other side, e.g. top side, of the cavity or cavity structure. The cavity can be defined with the full incorporation of the ITO thickness. The interfaces above the ITO and the N—GaN are the two boundary conditions. The metal layer 403 acts as the bottom side mirror and the distributed Bragg reflector 601 acts as the top side mirror, thereby facilitating the resonant cavity structure.

Generally, applications that require devices made in a compound semiconductor, especially are tightly co-integrated with CMOS logic, such as AR glasses, head up displays, micro-projectors, and the like need cost effective micro-LED displays with a very tight pitch (3 um or below), very large arrays (e.g. Full High Definition, 1920×1280 pixels). These applications further require integration of the micro-LED displays with optical system, like holographic waveguides, that require a specific emission angle from the light source to ensure good optical coupling and overall system efficiency.

Moreover, high brightness (1M nits) is also required for outdoors application. Standard LEDs are Lambertian emitters and thus inherently inefficient for light coupling to those optical solutions, while RCLED have much narrow emission angle and thus higher coupling efficiency. Furthermore, RCLEDs provide much higher electrical efficiency and thus less power consumption to achieve the required high brightness. Finally, the ability to process III-V compound semiconductor in an already established Si-CMOS 300 mm line ensures the most cost effective, and fast approach to the market.

The application proposes a new approach to fabricate RCLED on GaN material in a full CMOS environment with hybrid W2W bonding backplane integration for micro-LED displays using an innovative stopping layer for CMP etching for cavity length definition. The approach is defined by the ability to process III-V material in a 300 mm CMOS line. The solution presented herein allows better electrical performances, lower consumption, better optical efficiency and in general better overall performances for micro-LED displays for various applications, enabling at the same time the cost-effective measures of a Si-CMOS 300 mm line.

It is important to note that the word “comprising” does not exclude other elements or steps and the indefinite article “a” or “an” does not exclude a plurality. A single element or other unit may fulfill the functions of several entities or items recited in the claims. Moreover, the description with regard to any of the aspects is also relevant with regard to the other aspects of the invention.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with to only respect one of several implementations, such feature may be combined with one or more other features of the other implementations as may be desired and advantageous for any given or particular application.

1.-15. (canceled)

16. A method for forming resonant cavity light emitting elements, the method comprising:
forming a first structure comprising a first substrate, a stop layer, a light emitting epitaxial structure, a conductive oxide layer, and a second substrate dielectrically bonded to the conductive oxide layer;
etching from the first substrate up to the stop layer;
forming a plurality of light emitting mesa modules, each having a metal layer deposited on the stop layer;
hybrid bonding the first structure to a carrier substrate to form a second structure;
etching from the second substrate up to the conductive oxide layer; and
depositing a distributed Bragg reflector on top of the conductive oxide layer, thereby forming the resonant cavity light emitting elements.

17. The method of claim 16, wherein a thickness of the stop layer, the light emitting epitaxial structure, and the conductive oxide layer, collectively, defines a cavity length for the resonant cavity light emitting elements.

18. The method of claim 17, wherein the cavity length corresponds to about one wavelength of a light to be emitted by the resonant cavity light emitting elements.

19. The method of claim 16, further comprising forming the first structure by:
growing a buffer layer, the stop layer, the light emitting epitaxial structure, and the conductive oxide layer, successively, on the first substrate, the light emitting epitaxial structure successively having a first highly-doped layer, an emission layer, and a second highly-doped layer;
providing the stop layer between the buffer layer and the first highly-doped layer; and
dielectric bonding to the second substrate at the conductive oxide layer to form the first structure.

20. The method of claim 19, wherein the buffer layer is an n-doped buffer layer, the first highly-doped layer is an n-type dopant, the second highly-doped layer is a p-type dopant, and/or the emission layer is a quantum well layer.

21. The method of claim 20, wherein the n-doped buffer layer is an n-type Gallium Nitride (n-GaN) layer, the first highly-doped n-type layer is an n-type Gallium Nitride (n-GaN) layer, the second highly-doped p-type layer is a p-type Gallium Nitride (p-GaN) layer, and/or the quantum well layer is Indium Gallium Nitride (InGaN) or Gallium Nitride (GaN) based multiple quantum well (MQW) multi-layer.

22. The method of claim 16, wherein the stop layer is an Indium Gallium Nitride (InGaN) layer, an Aluminum Indium Gallium Nitride (AlInGaN) layer, an Aluminum Gallium Nitride (AlGaN) layer, or a dielectric layer.

23. The method of claim 22, wherein the dielectric layer is an oxide based dielectric material.

24. The method of claim 16, further comprising forming the second structure by:
flipping over the first structure after forming the plurality of light emitting mesa modules; and
hybrid bonding the first structure to the carrier substrate comprising a plurality of contact pads so as to bond the plurality of light emitting mesa modules with the respective contact pads.

25. The method of claim 1, wherein the conductive oxide layer is an optically transparent oxide layer.

26. The method of claim 25, wherein the optically transparent oxide layer is a transparent oxide based alloy.

27. The method of claim 1, wherein the metal layer comprises a titanium layer, an aluminum layer, or bilayers thereof.

28. The method of claim 1, wherein the metal layer contains a plurality of conductive layers comprising titanium based oxide layers, hafnium based oxide layers, or bilayers thereof.

29. The method of claim 1, wherein the metal layer comprises a plurality of dielectric layers and at least one metallic layer to form a hybrid optical reflector.

30. The method of claim 1, wherein the distributed Bragg reflector is a multi-layer oxide based reflector comprising tantalum based oxide layers, niobium based oxide layers, silicon based oxide layers, or bilayers thereof.

31. The method of claim 1, wherein the etching comprises a dry etching process, a chemical-mechanical planarization process, a combination thereof.

32. The method of claim 1, wherein the stop layer has a thickness less than about 20 nm.

33. The method of claim 32, wherein the stop layer has a thickness ranging from between about 10 to about 15 nm.

34. An optical device comprising a plurality of resonant cavity light emitting elements, each of the plurality of resonant cavity light emitting elements comprising:
a carrier substrate;
a metal layer hybrid bonded with the carrier substrate;
a stop layer on top of the metal layer;
a first highly-doped layer on top of the stop layer;
an emission layer on top of the first highly-doped layer;
a second highly-doped layer on top of the emission layer;
a conductive oxide layer on top of the second highly-doped layer; and
a distributed Bragg reflector on top of the conductive oxide layer.

35. The optical device of claim 34, wherein the stop layer, the first highly-doped layer, the emission layer, the second highly-doped layer, and the conductive oxide layer are configured to define a cavity length for the resonant cavity light emitting elements that corresponds to about one wavelength of a light to be emitted by the resonant cavity light emitting elements.
